(19) United States
(12) Patent Application Publication
(10) Pub. No.: US 2011/0240966 A1
(43) Pub. Date: Oct. 6, 2011

(54) Organic Electroluminescent Device

(75) Inventors: Russell Lees, Ely (GB); Angela Lees, Ely (GB); William Young, Cambridge (GB)

(73) Assignee: Cambridge Display Technology Limited, Cambridgeshire (GB)

(21) Appl. No.: 13/058,739

(22) PCT Filed: Aug. 21, 2009
(86) PCT No.: PCT/GB2009/002051

§ 371 Date: May 3, 2011

(30) Foreign Application Priority Data
Aug. 21, 2008 (GB) 0815286.0

(51) Int. Cl. H01L 51/52; H01L 51/56

(52) U.S. Cl. 257/40; 438/26; 257/E51.018; 257/E51.001

(57) ABSTRACT

An organic electroluminescent device comprising: a substrate; a first electrode disposed over the substrate for injecting charge of a first polarity; a second electrode disposed over the first electrode for injecting charge of a second polarity opposite to said first polarity; an organic light emitting layer disposed between the first and the second electrode; an encapsulant can disposed over, and spaced apart from, the second electrode, defining a cavity therebetween; wherein a plurality of spacers are disposed between the encapsulant can and the second electrode forming multiple sealed cavities between the second electrode and the encapsulant can.

### FIELD OF THE INVENTION

The present invention relates to an organic electroluminescent device and a method of manufacture thereof.

### BACKGROUND OF THE INVENTION

Organic electroluminescent devices are known, for example, from PCT/WO/13148 and U.S. Pat. No. 4,539,507. Examples of such devices are shown in FIGS. 1 and 2. Such devices generally comprise: a substrate 2; a first electrode 4 disposed over the substrate 2 for injecting charge of a first polarity; a second electrode 6 disposed over the first electrode 4 for injecting charge of a second polarity opposite to said first polarity; an organic light emitting layer 8 disposed between the first and the second electrodes; and an encapsulant 10 disposed over the second electrode 6. In one arrangement shown in FIG. 1, the substrate 2 and first electrode 4 are transparent to allow light emitted by the organic light-emitting layer 8 to pass therethrough. In another arrangement shown in FIG. 2, the second electrode 6 and the encapsulant 10 are transparent so as to allow light emitted from the organic light-emitting layer 8 to pass therethrough.

Variations of the above described structures are known. The first electrode may be the anode and the second electrode may be the cathode. Alternatively, the first electrode may be the cathode and the second electrode may be the anode. Further layers may be provided between the electrodes and the organic light-emitting layer in order to aid charge injection and transport. The organic material in the light-emitting layer may comprise a small molecule, a dendrimer or a polymer and may comprise phosphorescent moieties and/or fluorescent moieties. The light-emitting layer may comprise a blend of materials including light emitting moieties, electron transport moieties and hole transport moieties. These may be provided in a single molecule or in separate molecules.

By providing an array of devices of the type described above, a display may be formed comprising a plurality of emitting pixels. The pixels may be of the same type to form a monochrome display or they may be different colours to form a multicolour display.

As an alternative, or in addition to, a thin film encapsulant disposed over the top electrode of an organic electroluminescent device, an encapsulant can may be provided over the device to encapsulate the device against moisture and oxygen ingress. The encapsulant can may be, for example, a metal can or a layer of glass or plastic having a recess therein forming an encapsulant can to receive the device and provide a seal around the periphery of the device. The recess is generally deep enough to space the encapsulant can from the upper surface of the device in order to prevent the upper surface of the top electrode being damaged during encapsulation. A cavity is thus formed between the upper surface of the top electrode and the encapsulant can. Such an arrangement is illustrated in FIG. 3 comprising: a substrate 2; a first electrode 4 disposed over the substrate 2 for injecting charge of a first polarity; a second electrode 6 disposed over the first electrode 4 for injecting charge of a second polarity opposite to the first polarity; and an organic light emitting layer 8 disposed between the first and the second electrode. A thin film encapsulant (not shown) may be optionally disposed over the second electrode 6. An encapsulant can 14 having a recess formed therein is disposed over the aforementioned layers and bonded to the substrate 2 with an adhesive 16 around the periphery of the organic electroluminescent device. The encapsulant can 14 is spaced from the upper surface of the top electrode 6 forming a cavity 18.

A problem associated with prior art arrangements is column defects caused by cathode damage. One cause of cathode damage in large cavity displays has been attributed to encapsulant can bowing during manufacture and handling resulting in the can contacting and damaging the cathode. As can be seen in FIG. 4 where the area is quite large over which a can or encapsulant is positioned there is susceptibility to bowing which can lead to damage in the active area especially in the middle.

Use of spacer elements between the top electrode and the sealing can to maintain a gap between the can and the cathode is known for example in US2004/0004436 and JP2002147500. However, there is an ongoing need for improved encapsulation and especially to prevent ingression of oxygen and moisture as well as bowing.

### SUMMARY OF THE INVENTION

The present applicants have identified that single bead spacers do not solve the problem of oxygen and moisture ingression in cavities. It is an aim of the present invention therefore to address this problem.

The present inventors have realised that disposition of lines of spacers and not just individual beads of spacers provide improved prevention of bowing as well as preventing ingression of oxygen and moisture. In particular, the present inventors have realised that multiple cavities over a display to both maintain a gap between the encapsulant can and the top electrode can be formed and so as to improve protection against water and or oxygen ingress by providing multiple internal seals preventing any water/oxygen which penetrates the outer seal from diffusing over the whole display. Encapsulants forming multiple sealed cavities over a display have also not been previously disclosed. The spacers disclosed in the prior art are single beads. According to embodiments of the present invention lines of spacers are provided which form multiple sealed cavities. This arrangement has been found to solve the aforementioned problems.

Accordingly, one aspect of the present invention provides an organic electroluminescent device comprising: a substrate; a first electrode disposed over the substrate for injecting charge of a first polarity; a second electrode disposed over the first electrode for injecting charge of a second polarity opposite to said first polarity; an organic light emitting layer disposed between the first and the second electrode, an encapsulant body or can disposed over, and spaced apart from, the electrode, defining a cavity therebetween; wherein a plurality of spacers are disposed between the encapsulant body or can and the second electrode forming multiple sealed cavities between the second electrode and the encapsulant body or can.

Another aspect of the present invention provides a method of manufacturing an organic electroluminescent device comprising the steps: depositing a first electrode over a substrate for injecting a charge of a first polarity; depositing an organic light emitting layer over the first electrode; depositing a second electrode over the organic light emitting layer for injecting charge of a second polarity opposite to said first polarity; disposing an encapsulant can over, and spaced apart from, the second electrode, defining a cavity therebetween; wherein a plurality of spacers are disposed between the encapsulant can and the second electrode forming multiple sealed cavities between the second electrode and the encapsulant can.

The previously identified problem has therefore been solved by using spacers to space the inside of the encapsulant can from the top electrode while also forming multiple sealed cavities.

In a preferred embodiment the plurality of spacers comprise a plurality of intersecting lines of sealant material forming the multiple sealed cavities between the second electrode and the encapsulant can. Spacers such as glue lines can be disposed between the can and the cathode with an outer peripheral glue line sealing the can to the substrate.

The present invention relates to multiple cavities covering a single display.

Advantages resulting from the arrangement of the present invention include increasing the can rigidity and the formation of multiple internal seals which are able to provide protection against water and/or oxygen diffusion over the whole display.

### BRIEF DESCRIPTION OF THE DRAWINGS

Embodiments of the present invention will now be described by way of example only with reference to the accompanying drawings, in which:

FIG. 1 shows a known structure of a bottom-emitting organic light emitting device.

FIG. 2 shows a known structure of a top-emitting organic light emitting device.

FIG. 3 shows a known structure of an organic light emitting device with an encapsulant can disposed thereover.

FIG. 4 shows a typical example of the problem of can bowing in prior art arrangements.

FIG. 5 shows a cross sectional view of a device in accordance with an embodiment of the present invention.

FIG. 6 shows a cross sectional view of a device in accordance with an embodiment of the present invention wherein the getter material is recessed in the encapsulant.

FIG. 7 shows a top down view of the inside of the encapsulant in accordance with an embodiment of the present invention.

FIG. 8 shows the top down view of the glue around the edge of a display in accordance with an embodiment of the present invention.

FIG. 9 shows a top down view of multiple displays on a substrate in accordance with an embodiment of the present invention.

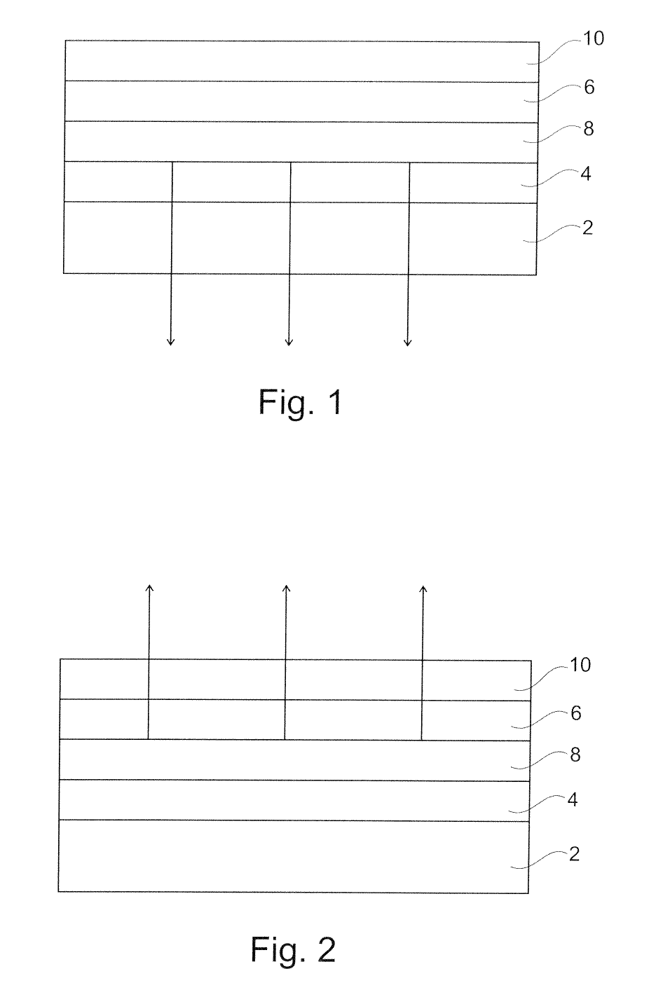

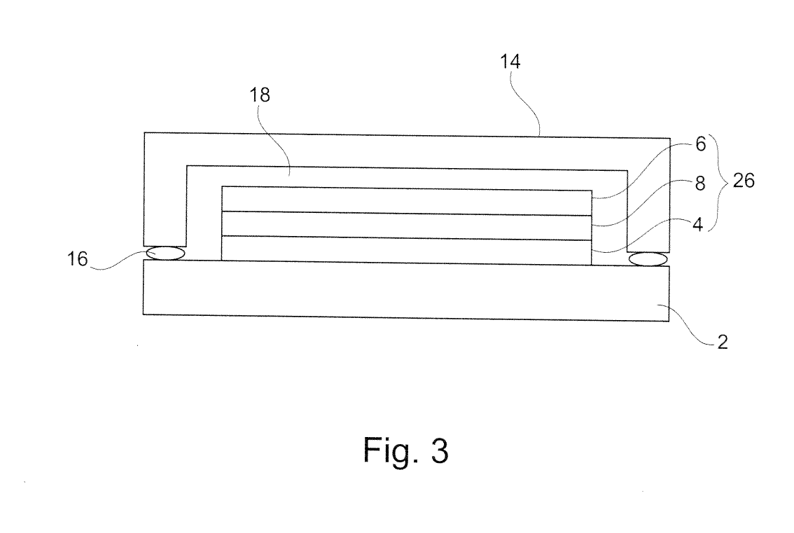

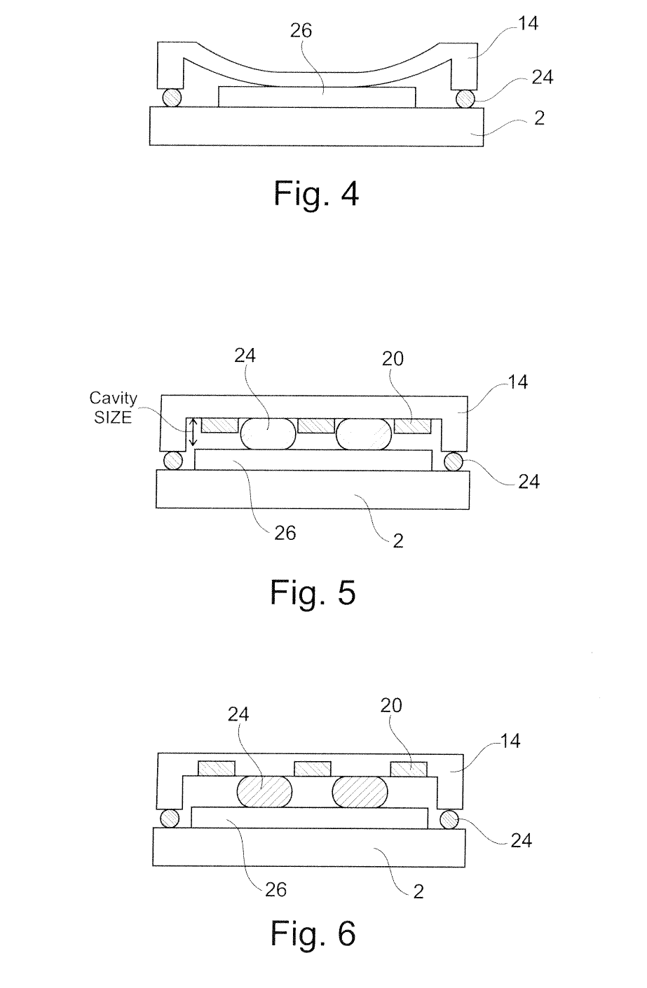

### DETAILED DESCRIPTION OF EMBODIMENTS OF THE PRESENT INVENTION

FIG. 5 illustrates a device in accordance with the present invention. A first electrode 4 is disposed over the substrate 2 for injecting charge of a first polarity. A second electrode 6 is disposed over the first electrode 4 for injecting charge of a second polarity opposite to said first polarity. An organic light emitting layer 8 is disposed between the first 4 and the second electrode 8. An encapsulant can 14 is disposed over, and spaced apart from, the second electrode 6, defining a cavity therebetween; wherein a plurality of spacers 24 are disposed on the inside of the encapsulant 14 forming multiple sealed cavities between the second electrode 6 and encapsulant 14.

The presence of spacers 24 forming multiple sealed cavities reduces the problem of can 14 bowing.

It is preferable with the present invention to provide a getter material 20 in the cavities. Such getter material 20 should be soft and can be, without being especially limited, an adhesive tab for example. The getter material 20 can be beneficial and is provided for absorption of any atmospheric moisture and/or oxygen that may permeate through the substrate 2 or encapsulant 14.

The spacer 24 used in the present invention is preferably an adhesive. A peripheral spacer 24 seals the can 14 to the substrate 2.

Without being especially limited the adhesive can be an epoxy resin. Use of an epoxy resin is advantageous since the glue can bond to the substrate 2 and the top cathode 6 of the device 26 more easily and hence result in a more stable structure.

Preferably the spacers 24 are UV and/or thermally curable. In a more preferred embodiment where the spacers 24 are thermally curable, they are thermally curable at a temperature below 80° C. Such a temperature allows for a safer curing stage and easier manufacture conditions for the device.

In a further preferred embodiment when the spacer 24 employed is an adhesive it further comprises rigid, (i.e. substantially incompressible) particles which can aid in strengthening the adhesive. This ensures that the adhesive does not compress fully and get ‘squeezed out’ when the encapsulant 14 is disposed on the device 26 and substrate 2. This also results in a stronger joint. Without being especially limited such particles can be, for example, glass particles, silica particles or silicon carbide particles.

Preferably the size of such particles is in the range of 5 μm to 10 μm. This ensures the effects described above are achieved and also so that the adhesive is not too rigid so as to cause damage to the substrate 2 or active area 26 with which it comes into contact.

In a preferred embodiment the size of each cavity is in the range of 0.5 mm to 1 mm. More preferably the size of each cavity is between 0.5 mm and 0.7 mm. These sizes help to minimise the ingression of oxygen and water in the cavities.

The thickness of the lines 24 formed by the spacers 24 is not especially limited but preferably at least the same as that of the cavities to ensure that they are securely sealed.

FIG. 6 shows an alternative embodiment of the present invention in which the encapsulant 14 may comprise one or more recesses in which the getter material 20 is disposed.

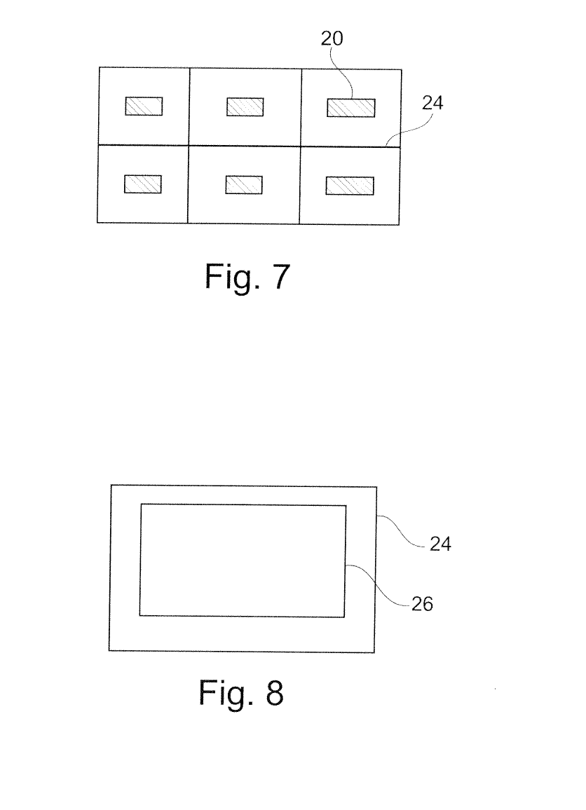

FIG. 7 illustrates the glue lines 24 which help form the multiple sealed cavities. FIG. 8 illustrates the peripheral glue lines 24 used to fix the can to the device.

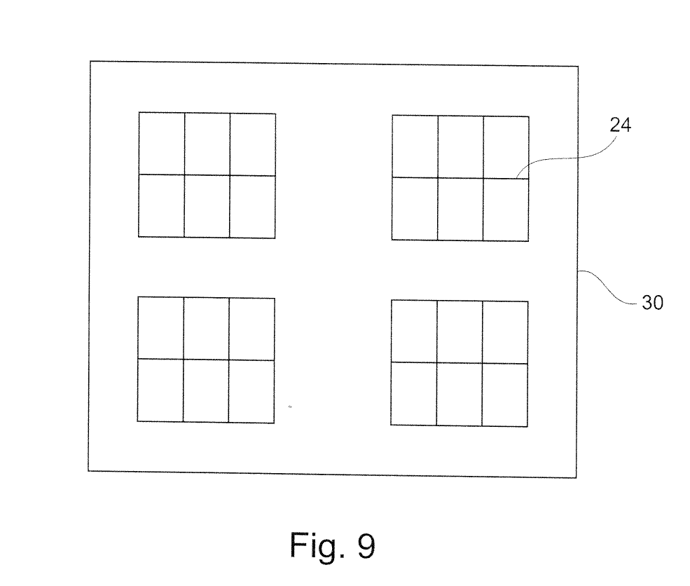

FIG. 9 shows a top down view of multiple displays on a substrate in accordance with an embodiment of the present invention. Without being especially limited the encapsulation in accordance with the present invention can be provided for displays that range from 3 inches to 14 inches in diagonal length. Preferably the encapsulation in accordance with the present invention is provided for 6 inch to 10 inch displays.

The plurality of displays can be manufactured on a single substrate and then separated by scoring or cutting of the substrate.

Regarding the method of manufacture of the device of the present invention the electrode layers and organic light emitting layer may be deposited by vapour deposition or may be solution processed by, for example, spin coating or inkjet deposition.

The spacers 24 can either be disposed on the inside of the encapsulant 14 can before depositing the can 14 on the device 26 or the spacers 24 can be disposed on the top electrode 6 of the device 26 before depositing the can 14 on the top electrode 6 of the device 26.

Curing of the spacers 24 can be carried out from the bottom upwards. However, this can be blocked by the electronics. Accordingly a top down cure may be employed. For example UV light can be used to cure the spacer 24 where it is for example a suitable epoxy resin. Preferably the cure takes place after the spacer 24 has adhered to the device 26 and substrate 2. Otherwise there is the possibility of damage being caused by cured and therefore rigid spacers coming down on the top electrode and substrate of the device.

Typically the temperature employed during curing will be less than 80° C., with a final bake temperature of up to 130° C.

Further features of organic electroluminescent devices according to embodiments of the present invention and their method of manufacture are discussed below.

### General Device Architecture

The architecture of the electroluminescent device according to embodiments of the invention comprises a glass or plastic substrate, an anode and a cathode. An electroluminescent layer is provided between the anode and the cathode.

In a practical device, at least one of the electrodes is semi-transparent in order that light may be absorbed (in the case of a photoresponsive device) or emitted (in the case of an OLED). Where the anode is transparent, it typically comprises indium tin oxide.

### Charge Transport Layers

Further layers may be located between the anode and the cathode, such as charge transporting, charge injecting or charge blocking layers.

In particular, it is desirable to provide a conductive hole injection layer, which may be formed from a conductive organic or inorganic material provided between the anode and the electroluminescent layer to assist hole injection from the anode into the layer or layers of semiconducting polymer. Examples of doped organic hole injection materials include doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and poly(thienothiophene). Examples of conductive inorganic materials include transition metal oxides such as VOx MoOx and RuOx as disclosed in Journal of Physics D: Applied Physics (1996), 29(11), 2750-2753.

If present, a hole transporting layer located between the anode and the electroluminescent layer preferably has a HOMO level of less than or equal to 5.5 eV, more preferably around 4.8-5.5 eV. HOMO levels may be measured by cyclic voltammetry, for example.

If present, an electron transporting layer located between electroluminescent layer and the cathode preferably has a LUMO level of around 3-3.5 eV.

### Electroluminescent Layer

The electroluminescent layer may consist of the electroluminescent material alone or may comprise the electroluminescent material in combination with one or more further materials. In particular, the electroluminescent material may be blended with hole and/or electron transporting materials as disclosed in, for example, WO 99/48160, or may comprise a luminescent dopant in a semiconducting host matrix. Alternatively, the electroluminescent material may be covalently bound to a charge transporting material and/or host material.

The electroluminescent layer may be patterned or unpatterned. A device comprising an unpatterned layer may be used an illumination source, for example. A white light emitting device is particularly suitable for this purpose. A device comprising a patterned layer may be, for example, an active matrix display or a passive matrix display. In the case of an active matrix display, a patterned electroluminescent layer is typically used in combination with a patterned anode layer and an unpatterned cathode. In the case of a passive matrix display, the anode layer is formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed by photolithography.

Suitable materials for use in the electroluminescent layer include small molecule, polymeric and dendrimeric materials, and compositions thereof. Suitable electroluminescent polymers for use in the electroluminescent layer include poly(arylene vinylenes) such as poly(p-phenylene vinylenes) and polyarylenes such as: polyfluorenes, particularly 2,7-linked 9,9 dialkyl polyfluorenes or 2,7-linked 9,9 diaryl polyfluorenes; polyspirofluorenes, particularly 2,7-linked poly-9,9-spirofluorene; polyindenofluorenes, particularly 2,7-linked polyindenofluorenes; polyphenylenes, particularly alkyl or alkoxy substituted poly-1,4-phenylene. Such polymers as disclosed in, for example, Adv. Mater. 2000 12(23) 1737-1750 and references therein. Suitable electroluminescent dendrimers for use in the electroluminescent layer include electroluminescent metal complexes bearing dendrimeric groups as disclosed in, for example, WO 02/066552.

### Cathode

The cathode is selected from materials that have a workfunction allowing injection of electrons into the electroluminescent layer. Other factors influence the selection of the cathode such as the possibility of adverse interactions between the cathode and the electroluminescent material. The cathode may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode will comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Optical devices tend to be sensitive to moisture and oxygen. Accordingly, the substrate preferably has good barrier properties for prevention of ingress of moisture and oxygen into the device. The substrate is commonly glass. However, alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is encapsulated with an encapsulant to prevent ingress of moisture and oxygen. A getter material for absorption of any atmospheric moisture and/or oxygen that may permeate through the substrate or encapsulant may be disposed between the substrate and the encapsulant.

### Other

The device may be formed by firstly forming an anode on a substrate followed by deposition of an electroluminescent layer and a cathode. However, it will be appreciated that the device of the invention could also be formed by firstly forming a cathode on a substrate followed by deposition of an electroluminescent layer and an anode.

### Solution Processing

A single polymer or a plurality of polymers may be deposited from solution to form the organic layer(s) of the device. Suitable solvents for polyarylenes, in particular polyfluorenes, include mono- or poly-alkylbenzenes such as toluene and xylene. Particularly preferred solution deposition techniques are spin-coating and inkjet printing.

Spin-coating is particularly suitable for devices wherein patterning of the electroluminescent material is unnecessary—for example for lighting applications or simple monochrome segmented displays.

Inkjet printing is particularly suitable for high information content displays, in particular full colour displays. Inkjet printing of OLEDs is described in, for example, EP 0880303.

Other solution deposition techniques include dip-coating, roll printing and screen printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

Overall the present invention makes for a more robust structure for an electroluminescent display device, wherein bowing of encapsulant and can covers leading to OLED active area scraping and damage is prevented and a thin and compact display, which can be made in batch process, can be obtained.

While this invention has been particularly shown and described with reference to preferred embodiments thereof, it will be understood by those skilled in the art that various changes in form and details may be made therein without departing from the scope of the invention as defined by the appended claims.

1. An electroluminescent device comprising:
a substrate;
a first electrode disposed over the substrate for injecting charge of a first polarity;
a second electrode disposed over the first electrode for injecting charge of a second polarity opposite to said first polarity;
an organic light emitting layer disposed between the first and the second electrode; and,
an encapsulant body disposed over, and spaced apart from, the second electrode, defining a cavity therebetween;
wherein a plurality of spacers are disposed between the encapsulant body and the second electrode forming multiple sealed cavities between the second electrode and the encapsulant body.

2. The device according to claim 1 wherein the plurality of spacers comprise a plurality of intersecting lines of sealant material forming the multiple sealed cavities between the second electrode and the encapsulant body.

3. The device according to claim 1 wherein getter material is provided in the cavities.

4. The device according to claim 3 wherein the encapsulant comprises one or more recesses in which the getter material is disposed.

5. The device according to claim 1 wherein the spacers comprise an adhesive.

6. The device according to claim 5 wherein the adhesive is an epoxy resin.

7. The device according to claim 1 wherein the spacers are UV curable and/or thermally curable.

8. The device according to claim 1 wherein the spacers are thermally curable at a temperature of less than 80° C.

9. The device according to claim 5 wherein the adhesive comprises spacer particles.

10. The device of claim 9 wherein the size of the spacer particles is in the range of 5 μm to 10 μm.

11. The device according to claim 1 wherein the size of each cavity is in the range of 0.5 mm to 1 mm.

12. The device of claim 1 wherein the size of each cavity is between 0.5 mm and 0.7 mm.

13. The device of claim 9 wherein the size of the spacer particles is at least the same size as that of the cavity.

14. A method of manufacturing an organic electroluminescent device comprising:
depositing a first electrode over a substrate for injecting a charge of a first polarity;
depositing an organic light emitting layer over the first electrode; and,
depositing a second electrode over the organic light emitting layer for injecting charge of a second polarity opposite to said first polarity; disposing an encapsulant body over, and spaced apart from, the second electrode, defining a cavity between the second electrode and the encapsulant body;
wherein a plurality of spacers are disposed between the encapsulant body and the second electrode forming multiple sealed cavities between the electrode and the encapsulant body.

15. The method according to claim 14 wherein the plurality of spacers comprise a plurality of intersecting lines of sealant material forming the multiple sealed cavities between the second electrode and the encapsulant body.

16. The method according to claim 14 wherein the spacers are disposed on the inside of the encapsulant body prior to placing the encapsulant body over the second electrode.

17. The method according to claim 14 wherein the spacers are disposed on the top surface of the second electrode prior to placing the encapsulant body over the second electrode.

18. The method according to claim 14 wherein the spacers are cured after the encapsulant body has been placed over the second electrode.

19. The method according to claim 14 wherein the spacers are cured from a top side of the organic electroluminescent device by UV light.
